(19) United States
(12) Patent Application Publication
(10) Pub. No.: US 2024/0407165 A1
(43) Pub. Date: Dec. 5, 2024

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventor: Yun Cheol HAN, Gyeonggi-do (KR)

(21) Appl. No.: 18/460,599

(22) Filed: Sep. 4, 2023

(30) Foreign Application Priority Data
Jun. 1, 2023 (KR) 10-2023-0070961

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A semiconductor device may include: a first gate structure; a second gate structure; an isolation insulation structure configured to extend in a first direction between the first gate structure and the second gate structure, and to have a first width in a second direction intersecting the first direction; and a first support located between the first gate structure and the second gate structure, and configured to have a second width greater than the first width in the second direction. The isolation insulation structure may protrude into the first support.

### CROSS-REFERENCE TO RELATED APPLICATION

This application claims priority under 35 U.S.C. § 119 to Korean Patent Application No. 10-2023-0070961 filed on Jun. 1, 2023, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is determined by an area occupied by a unit memory cell. Recently, as the improvement in the degree of integration of a semiconductor device for forming memory cells in a single layer on a substrate is reaching a limit, a three-dimensional semiconductor device for stacking memory cells on a substrate has been considered. Furthermore, in order to improve the operational reliability of such a three-dimensional semiconductor device, various structures and manufacturing methods have been developed.

### SUMMARY

In one embodiment, a semiconductor device may include: a first gate structure; a second gate structure; an isolation insulation structure configured to extend in a first direction between the first gate structure and the second gate structure, and to have a first width in a second direction intersecting the first direction; and a first support located between the first gate structure and the second gate structure, and configured to have a second width greater than the first width in the second direction, wherein the isolation insulation structure may protrude into the first support.

In another embodiment, a manufacturing method of a semiconductor device may include: forming a stack including first material layers and second material layers that are alternately stacked; forming first openings in the stack; forming a second opening located between the first openings, and the second opening having a greater size than the first openings; forming a support in the second opening; forming third openings that connect the first openings to each other between the first material layers and that expose the support by etching the second material layers through the first openings; and replacing the first material layers with third material layers through the third openings.

In another embodiment, a manufacturing method of a semiconductor device may include: forming a stack including first material layers and second material layers that are alternately stacked; forming first openings in the stack; forming a second opening having a greater size than the first openings by selectively expanding at least one of the first openings; forming a support in the second opening; forming third openings that connect the first openings to each other and that expose the support by etching the second material layers through the first openings; and forming a recess on a sidewall of the support exposed through the third openings.

### BRIEF DESCRIPTION OF THE DRAWINGS

FIGS. 1A to 1C are diagrams illustrating the structure of a semiconductor device in accordance with one embodiment.

FIG. 2A and FIG. 2B are diagrams illustrating the structure of a semiconductor device in accordance with another embodiment.

FIGS. 3A, 4A, 5A, 6A, 7A, 8A, 9A, and 10A, FIGS. 3B, 4B, 5B, 6B, 7B, 8B, 9B, and 10B, FIGS. 3C, 4C, 5C, 6C, 7C, 8C, 9C, and 10C, and FIGS. 3D, 4D, 5D, 6D, 7D, 8D, 9D, and 10D are diagrams for describing a manufacturing method of a semiconductor device in accordance with various of the detailed embodiments.

FIGS. 11A, 12A, 13A, 14A, and 15A, FIGS. 11B, 12B, 13B, 14B, and 15B, and FIGS. 11C, 12C, 13C, 14C, and 15C are diagrams for describing a manufacturing method of a semiconductor device in accordance with other detailed embodiments.

### DETAILED DESCRIPTION

Various embodiments are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical scope of the present disclosure will be described with reference to the accompanying drawings.

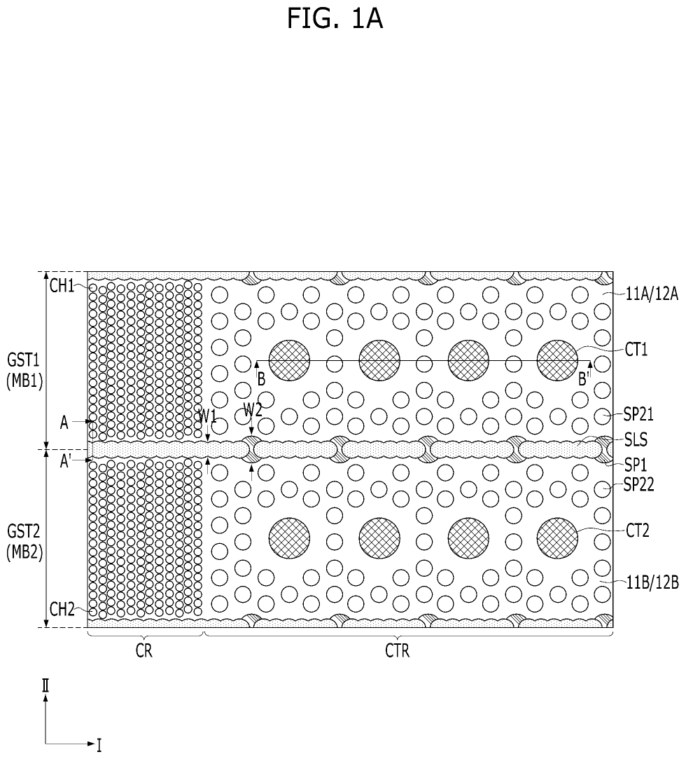

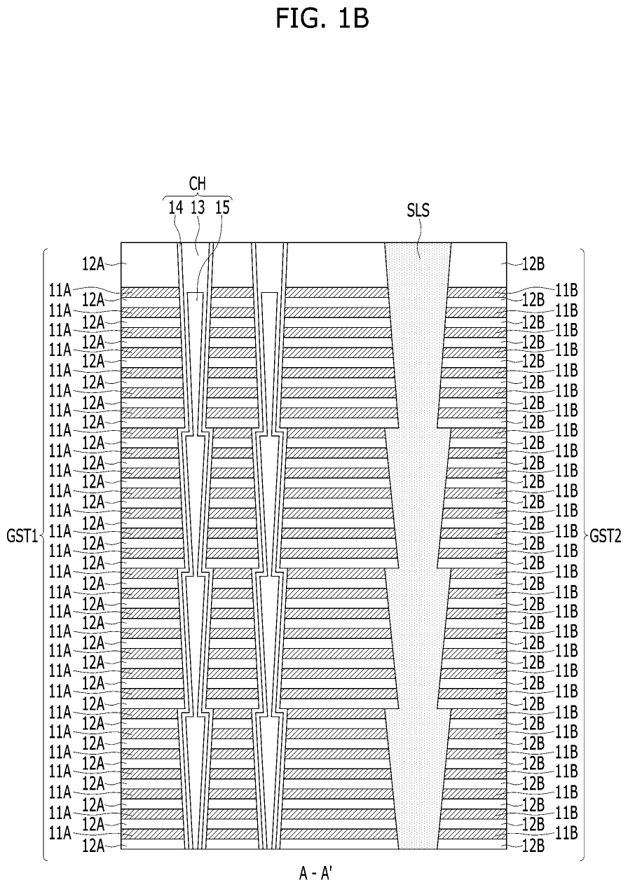

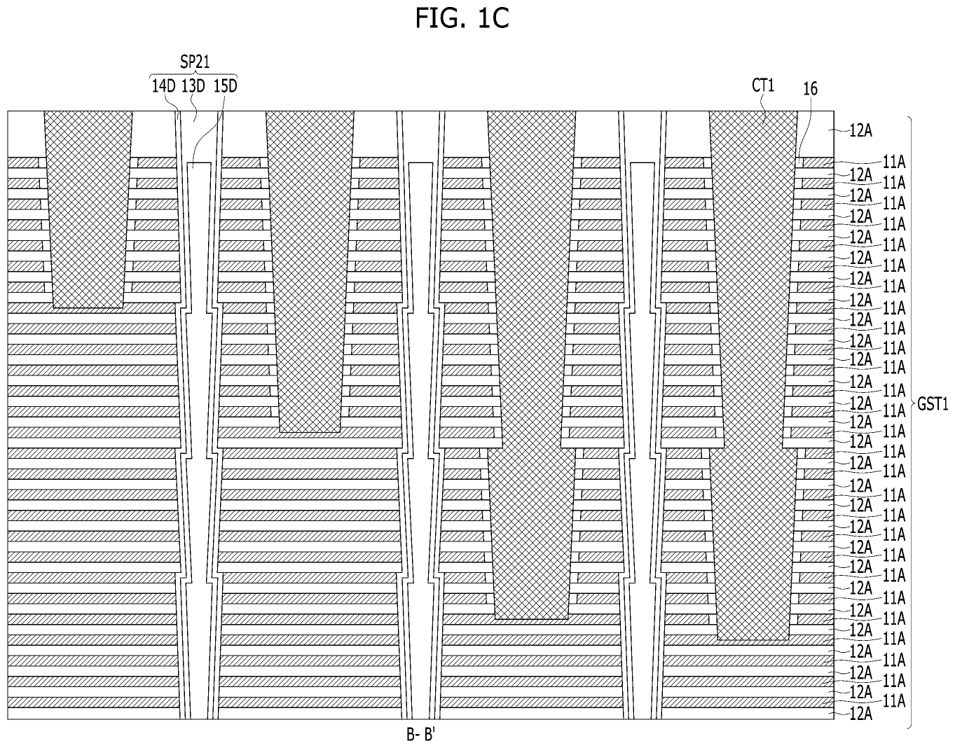

FIGS. 1A to 1C are diagrams illustrating the structure of a semiconductor device in accordance with one embodiment.

Referring to FIGS. 1A to 1C, the semiconductor device may include at least one or more of a first gate structure GST1, a second gate structure GST2, an isolation insulating structure IS, and first supports SP21. The semiconductor device may further include at least one or more of second supports SP22, a first channel structure CH1, a second channel structure CH2, first contact plugs CT1, second contact plugs CT2, and an insulating spacer 16.

As shown in FIGS. 1B and 1C, the first gate structure GST1 may include first conductive layers 11A and first insulating layers 12A that are alternately stacked. The first conductive layers 11A may be gate lines such as for example word lines, source select lines, and drain select lines. The first conductive layers 11A may each include a conductive material such as for example polysilicon and/or metal. The first insulating layers 12A are used to insulate the stacked first conductive layers 11A, and may each include one or more of an oxide, a nitride, an air gap, and the like. The first gate structure GST1 may belong to a first memory block MB1. A memory block may be a unit in which an erase operation is performed.

The first gate structure GST1 may include a cell region CR and a contact region CTR. The cell region CR may be a region where stacked memory cells are located, and the contact region CTR may be a region where an interconnection structure is located. The interconnection structure may include a contact plug, a wiring line, and the like, and may provide a path for transmitting a bias to the stacked memory cells. In one example, a peripheral circuit may be located below a cell array, and a row decoder may be located below the contact region CTR.

The first channel structure CH1 may extend through the cell region CR of the first gate structure GST1. The first channel structure CH1 may include at least one or more of a channel layer 13, a memory layer 14, and an insulating core 15. The memory layer 14 may include at least one or more of a tunneling layer, a data storage layer, and a blocking layer. The data storage layer may include one or more of a floating gate, polysilicon, a charge trap material, nitride, a variable resistance material, or the like. Memory cells may be located in a region where the first channel structure CH1 and the first conductive layers 11A intersect each other.

As shown in FIG. 1C, the first contact plugs CT1 may be electrically connected to the first conductive layers 11A in the contact region CTR. In one example, the first contact plugs CT1 may extend through the contact region CTR of the first gate structure GST1, and be connected to the first conductive layers 11A, respectively. The insulating spacers 16 may surround sidewalls of the first contact plugs CT1. In another example, the contact region CTR of the first gate structure GST1 may also include a step structure. In such a case, the first contact plugs CT1 may be respectively connected to the first conductive layers 11A exposed through the step structure.

The first support SP21 may extend through the contact region CTR of the first gate structure GST1. The first support SP21 may have a structure similar to that of the first channel structure CH1. In one example, the first support SP21 may include at least one or more of a dummy channel layer 13D, a dummy memory layer 14D, and a dummy insulating core 15D.

The second gate structure GST2 may have a structure similar to that of the first gate structure GST1. The second gate structure GST2 may include second conductive layers 11B and second insulating layers 12B that are alternately stacked. The second conductive layers 11B may be gate lines such as for example word lines, source select lines, and drain select lines. The second conductive layers 11B may each include a conductive material such as for example polysilicon and/or metal. The second insulating layers 12B are used to insulate the stacked second conductive layers 11B, and may include one or more of an oxide, a nitride, an air gap, and the like. The second gate structure GST2 may belong to a second memory block MB2.

The second gate structure GST2 may include a cell region CR and a contact region CTR. The second channel structure CH2 may extend through the cell region CR of the second gate structure GST1. The second contact plugs CT2 may be electrically connected to the second conductive layers 11B in the contact region CTR. The second support SP22 may extend through the contact region CTR of the second gate structure GST2. The second support SP22 may have a structure similar to that of the second channel structure CH2.

The first gate structure GST1 and the second gate structure GST2 may extend in a first direction I. The first gate structure GST1 and the second gate structure GST2 may be adjacent to each other in a second direction II intersecting the first direction I.

The isolation insulating structure IS may be located between the first gate structure GST1 and the second gate structure GST2. The isolation insulating structure IS may extend in the first direction I. In the second direction II, the isolation insulating structure IS may have a first width W1. The first width W1 may be a minimum width, a maximum width, or an average width. The isolation insulating structure IS may have irregularities on sidewalls thereof. Irregularities as used herein refer to structures of the sidewalls of the isolation insulating structure IS which cause the sidewalls to meander back and forth in the II direction shown in FIG. 1A. The isolation insulating structure IS may include at least one or more of an insulating material, a semiconductor material and/or a conductive material. The isolation insulating structure IS may include an insulating material such as for example one or more of an oxide, nitride, or an air gap. The isolation insulating structure IS may include a source contact structure electrically connected to a source layer.

The first support SP21 may be located between the first gate structure GST1 and the second gate structure GST2. The first support SP21 may be located between the contact region CTR of the first gate structure GST1 and the contact region CTR of the second gate structure GST2. The first support SP21 might not be located between the cell region CR of the first gate structure GST1 and the cell region CR of the second gate structure GST2.

In a plane defined by the first direction I and the second direction II shown by FIG. 1A, the first support SP21 may have a circular shape, an elliptical shape, a polygonal shape, or the like. The first supports SP21 may be arranged in the first direction I. In the second direction II, the first support SP21 may have a second width W2 greater than the first width W1. The first support SP21 may include an insulating material such as for example one or more of an oxide, a nitride, or an air gap.

The isolation insulating structure IS and the first support SP21 may be connected to each other. The first support SP21 may be located between a pair of isolation insulating structures IS. The isolation insulating structures IS and the first supports SP21 may be alternately arranged. The isolation insulating structure IS may protrude into the first support SP21.

According to the structure described above, in one embodiment, the connected isolation insulating structure IS and first support SP21 may constitute an isolation structure, and the isolation structure may be located at a boundary between memory blocks. Accordingly, the first gate structure GST1 and the second gate structure GST2 may be electrically isolated from each other by the isolation insulating structure IS and the first support SP21. Furthermore, the first memory block and the second memory block may be separately driven.

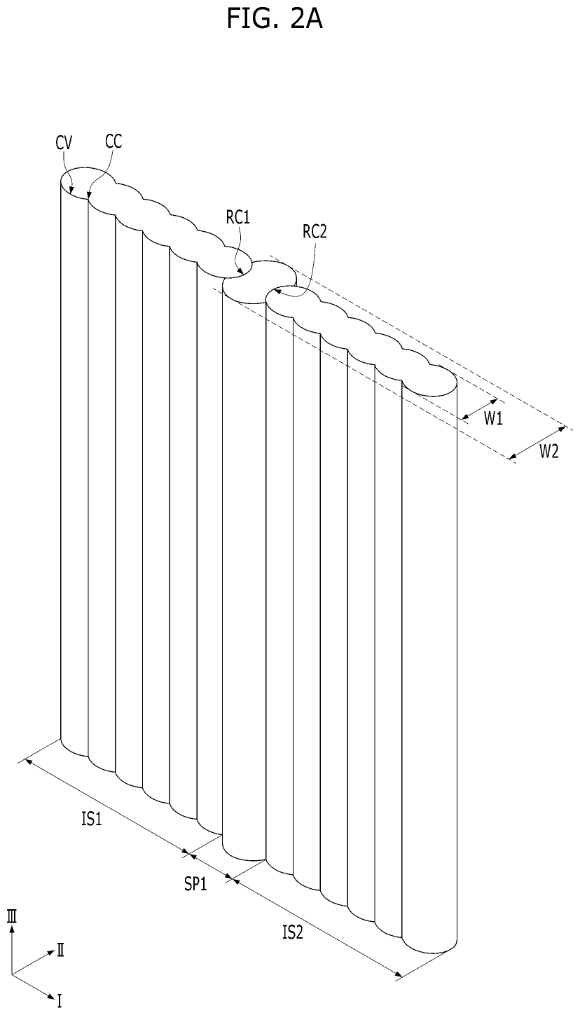

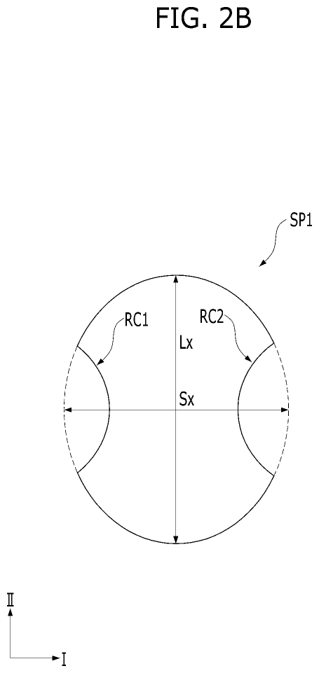

FIG. 2A and FIG. 2B are diagrams illustrating the structure of a semiconductor device in accordance with one embodiment. FIG. 2A is a perspective view of an isolation insulating structure IS and a first support SP1, and FIG. 2B is a layout of the first support SP1. Hereinafter, the content overlapping with the previously described content will be omitted.

Referring to FIGS. 2A and 2B, a first isolation insulating structure IS1 may extend in the first direction I. A second isolation insulating structure IS2 may be spaced apart from the first isolation insulating structure IS1 in the first direction I, and may extend in the first direction I. The first isolation insulating structure IS1 and the second isolation insulating structure IS2 may each include irregularities on sidewalls thereof. The first isolation insulating structure IS1 and the second isolation insulating structure IS2 may each include a convex portion CV and a concave portion CC on the sidewalls thereof.

The first support SP1 may be located between the first isolation insulating structure IS1 and the second isolation insulating structure IS2. In a plan view, as shown in FIG. 2B, the first support SP1 may have an elliptical shape. The first support SP1 may include a short axis Sx extending along the first direction I and a long axis Lx extending along the second direction II. The first support SP1 may include recesses RC1 and RC2 at portions connected to the first isolation insulating structure IS1 and the second isolation insulating structure IS2. In one example, the first support SP1 may include the recesses RC1 and RC2 located on the short axis Sx. A first recess RC1 and a second recess RC2 may face each other along the short axis Sx. The first isolation insulating structure IS1 may extend into the first recess RC1. The second isolation insulating structure IS2 may extend into the second recess RC2. A pair of first isolation insulating structure IS1 and second isolation insulating structure IS2 may protrude into the first support SP1.

According to the structure described above, in one embodiment, the first support SP1 may include the recesses RC1 and RC2 on sidewalls thereof, and the first isolation insulating structure IS1 and the second isolation structure IS1 may extend into the recesses RC1 and RC2. Accordingly, the first support SP1 may be used together with the first isolation insulating structure IS1 and the second isolation insulating structure IS2 as an isolation structure for electrically isolating gate structures from each other.

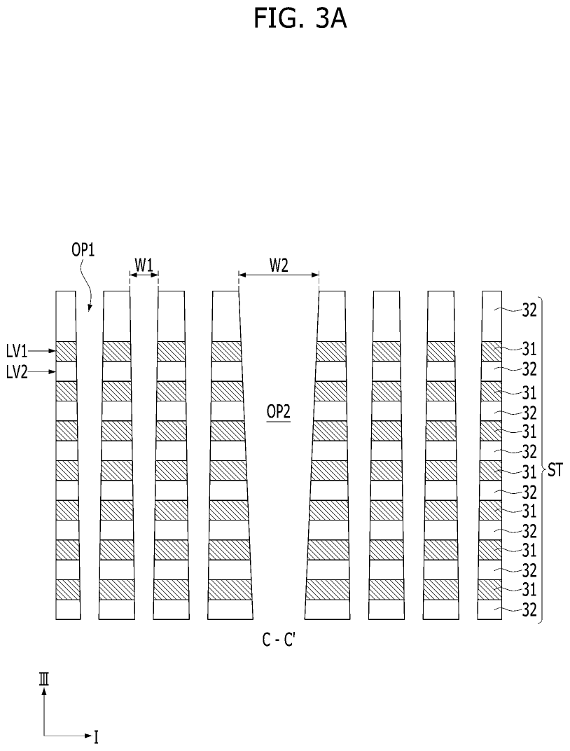

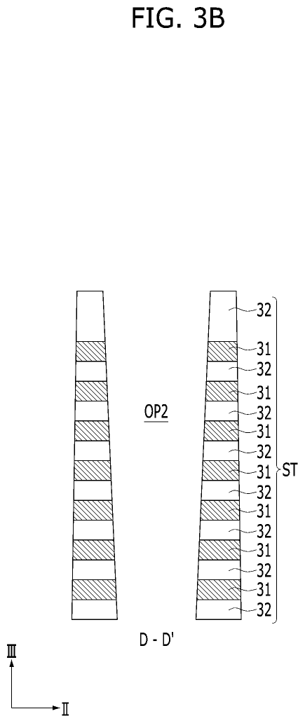

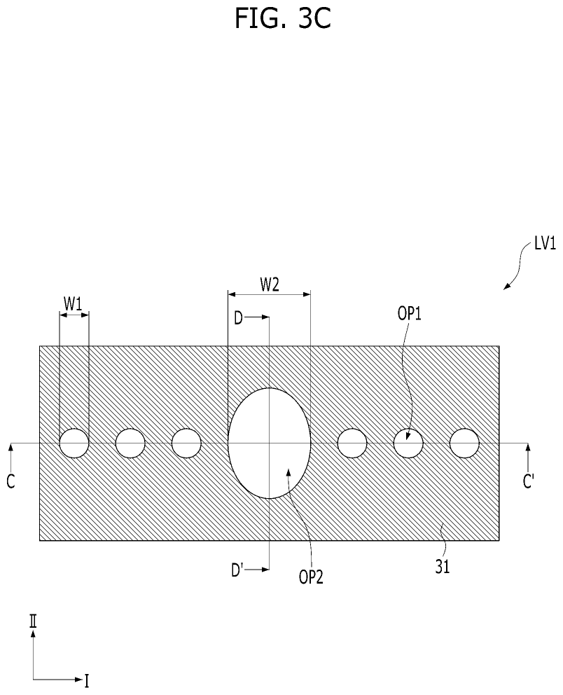

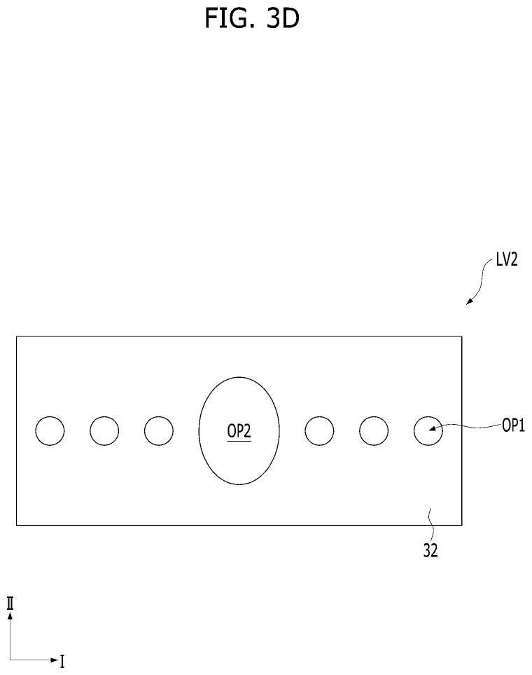

FIGS. 3A, 4A, 5A, 6A, 7A, 8A, 9A, and 10A, FIGS. 3B, 4B, 5B, 6B, 7B, 8B, 9B, and 10B, FIGS. 3C, 4C, 5C, 6C, 7C, 8C, 9C, and 10C, and FIGS. 3D, 4D, 5D, 6D, 7D, 8D, 9D, and 10D are diagrams for describing manufacturing methods for forming a semiconductor device in accordance with various of the detailed embodiments. FIGS. 3A, 4A, 5A, 6A, 7A, 8A, 9A, and 10A are cross-sectional views taken along lines C-C′ of FIGS. 3C, 4C, 5C, 6C, 7C, 8C, 9C, and 10C, respectively, and FIGS. 3B, 4B, 5B, 6B, 7B, 8B, 9B, and 10B are cross-sectional views taken along lines D-D′ of FIGS. 3C, 4C, 5C, 6C, 7C, 8C, 9C, and 10C, respectively. FIGS. 3C, 4C, 5C, 6C, 7C, 8C, 9C, and 10C are plan views of a first level LV1 of FIGS. 3A, 4A, 5A, 6A, 7A, 8A, 9A, and 10A, respectively, and FIGS. 3D, 4D, 5D, 6D, 7D, 8D, 9D, and 10D are plan views of a second level LV2 of FIGS. 3A, 4A, 5A, 6A, 7A, 8A, 9A, and 10A, respectively. Hereinafter, the content overlapping with the previously described content will be omitted.

Referring to FIGS. 3A to 3D, a stack ST including first material layers 31 and second material layers 32 that are alternately stacked may be formed. The first material layers 31 may each include a material having a high etching selectivity with respect to the second material layers 32. The first material layers 31 may be used to form gate lines such as for example select lines and/or word lines. In one example, the first material layers 31 may each include a sacrificial material such as a nitride and/or a conductive material such as polysilicon and/or metal. The second material layers 32 may be used to insulate the stacked gate lines from each other. The second material layers 32 may each include an insulating material such as for example one or more of an oxide, a nitride, or an air gap.

The stack ST may include a first level LV1 and a second level LV2. The first level LV1 may be a level at which the first material layers 31 are formed, and the second level LV2 may be a level at which the second material layers 32 are formed. As an example, the first level LV1 may be a level at which a gate line is to be formed and may be a level corresponding to a sacrificial material and/or a conductive material.

Subsequently, first openings OP1 may be formed in the stack ST. The first openings OP1 may extend in a third direction III into the stack ST. The third direction III may be a direction perpendicular to the plane defined by the first direction I and the second direction II. The first openings OP1 may be located at boundaries between adjacent memory blocks, and may be arranged along the first direction I. The first openings OP1 may be formed in a cell region and a contact region of the stack ST.

At least one second opening OP2 may be formed in the stack ST. The second opening OP2 may extend in the third direction III into the stack ST. The second opening OP2 may be located between the first openings OP1. The second opening OP2 may be formed in the contact region and might not be formed in the cell region. The first openings OP1 and the second opening OP2 may be arranged in the first direction I and aligned in the first direction I. When the first openings OP1 are formed, the second openings OP2 may be formed at the same time using the same etching process.

The first opening OP1 and the second opening OP2 may have substantially the same size or different sizes. As shown in FIG. 3C, the second opening OP2 may have a greater width than the first opening OP1. In one example, in the second direction II intersecting the first direction I, the first opening OP1 may have a first width W1 and the second opening OP2 may have a second width W2 greater than the first width W1. In a plan view, the first opening OP1 and the second opening OP2 may each have a circular shape, an elliptical shape, a polygonal shape, or the like. The first opening OP1 and the second opening OP2 may have the same shape or different shapes. As an example, the first opening OP1 may have a circular shape, and the second opening OP2 may have an elliptical shape. The second opening OP2 may have a short axis extending in the first direction I and a long axis extending in the second direction II.

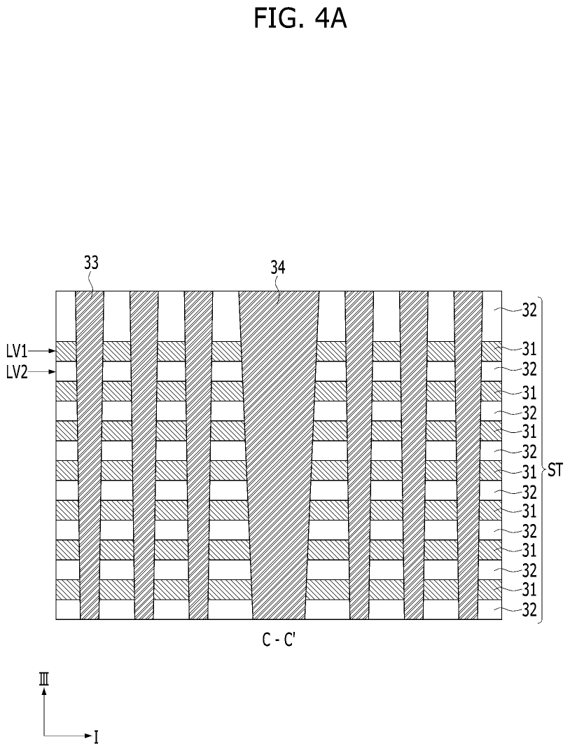

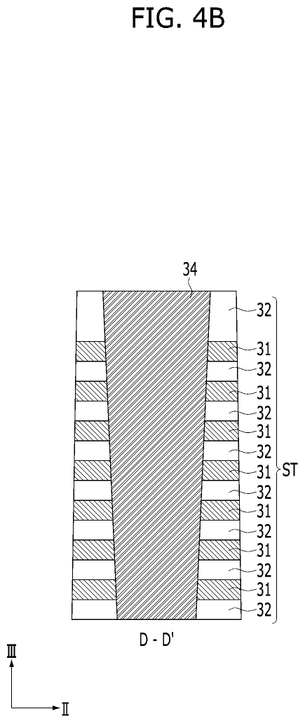

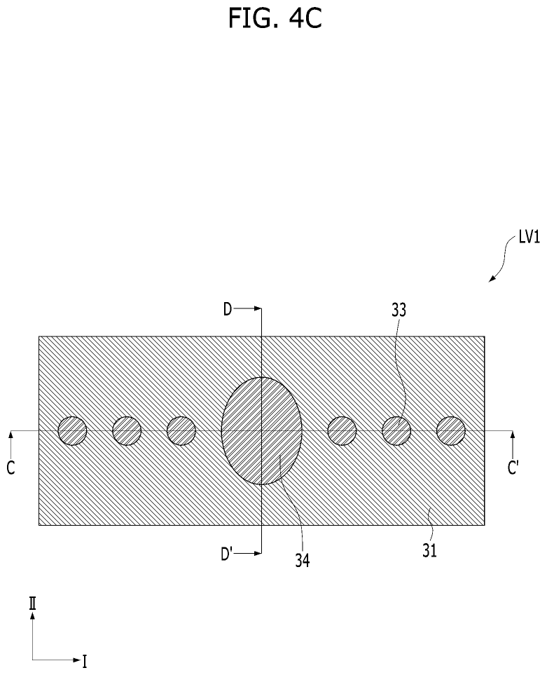

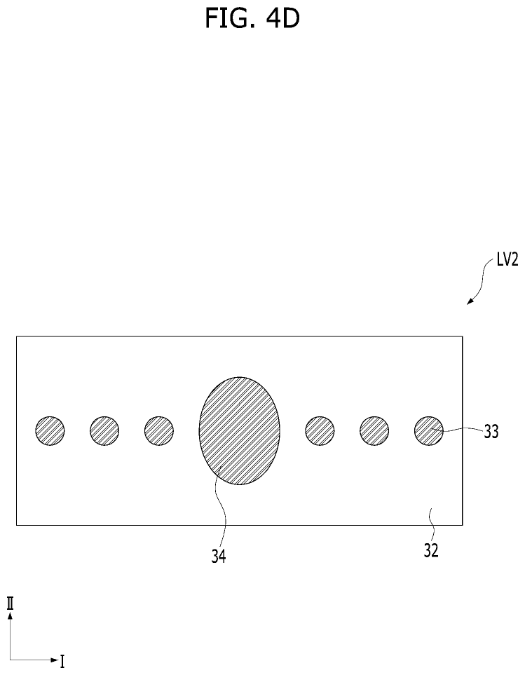

Referring to FIGS. 4A to 4D, first sacrificial layers 33 may be formed in the first openings OP1. A second sacrificial layer 34 may be formed in the second opening OP2. When the first sacrificial layers 33 are formed, the second sacrificial layer 34 may be formed at the same time using the same etching process. The first sacrificial layer 33 and the second sacrificial layer 34 may each include a material having a high etching selectivity with respect to the first material layers 31 and the second material layers 32. The first sacrificial layer 33 and the second sacrificial layer 34 may each include at least one or more of amorphous carbon, tungsten (W), polysilicon, and/or metal nitride. As an example, the first sacrificial layer 33 and the second sacrificial layer 34 may each include one or more of amorphous carbon and tungsten (W), amorphous carbon and polysilicon, polysilicon, or titanium nitride and tungsten (W).

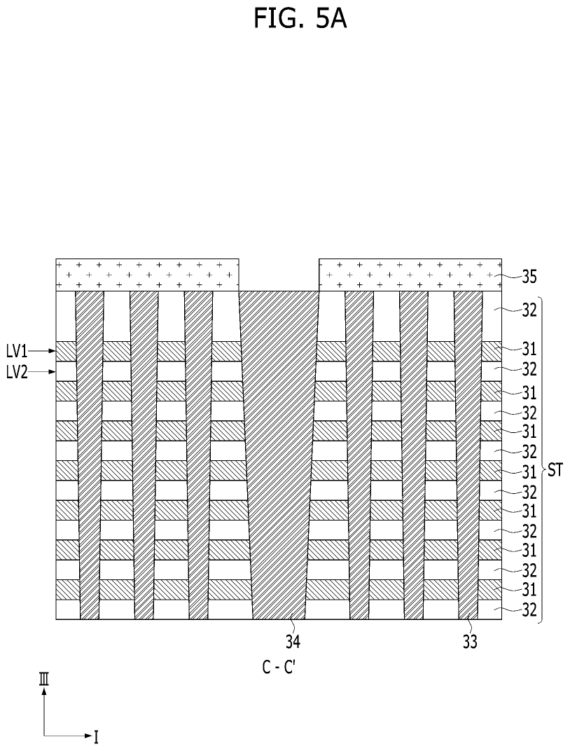

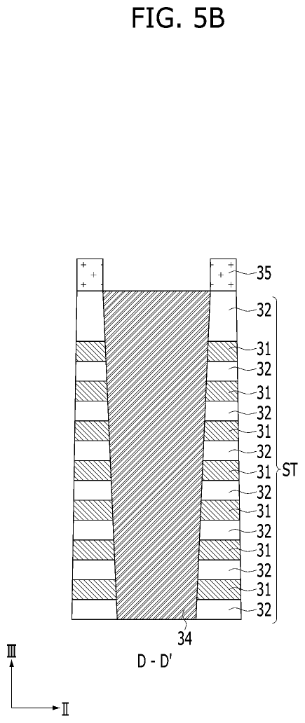

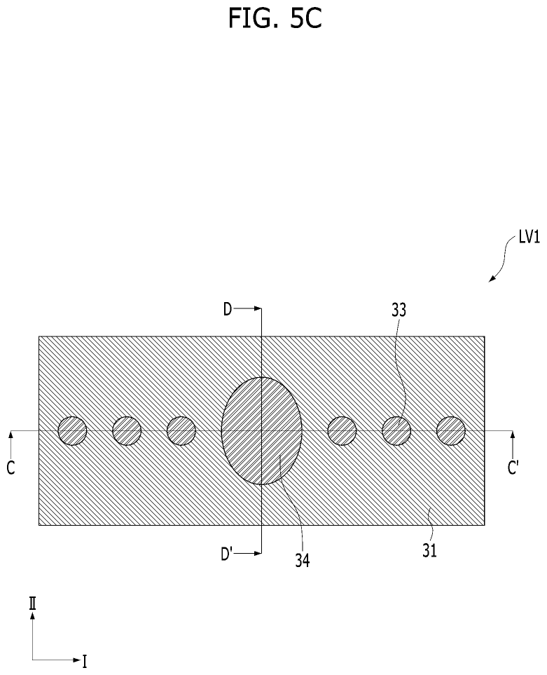

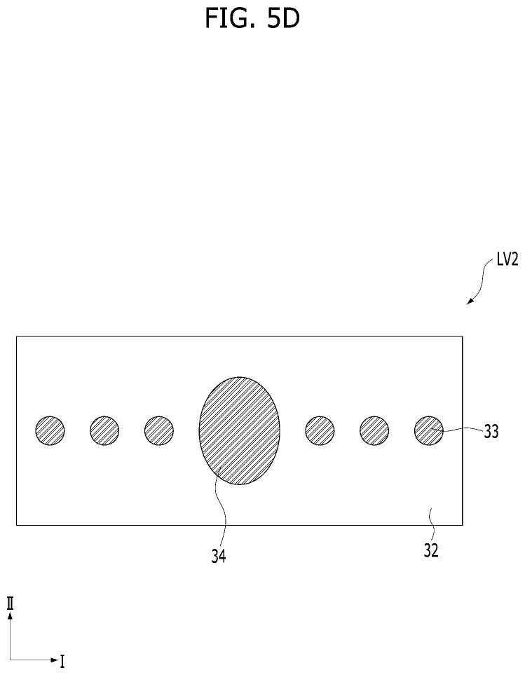

Referring to FIGS. 5A to 5D, a mask pattern 35 may be formed on the stack ST. The mask pattern 35 may cover the first sacrificial layers 33 and expose the second sacrificial layer 34. As an example, the mask pattern 35 may cover the cell region and may include an opening partly exposing the contact region. The opening may have a shape corresponding to the second sacrificial layer 34 and the second opening OP2, and may be located to correspond to the second sacrificial layer 34.

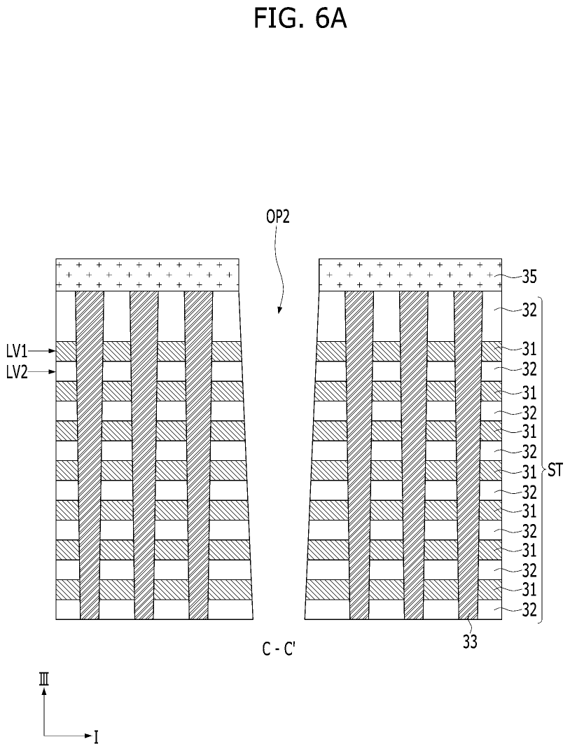

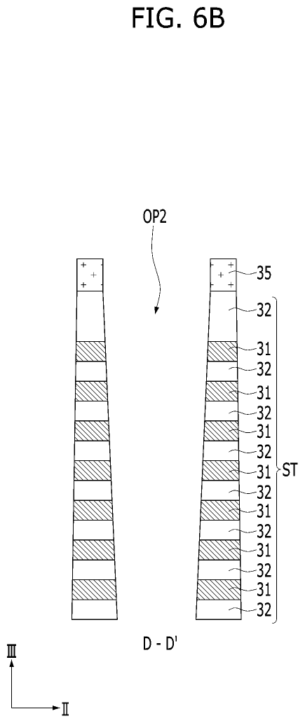

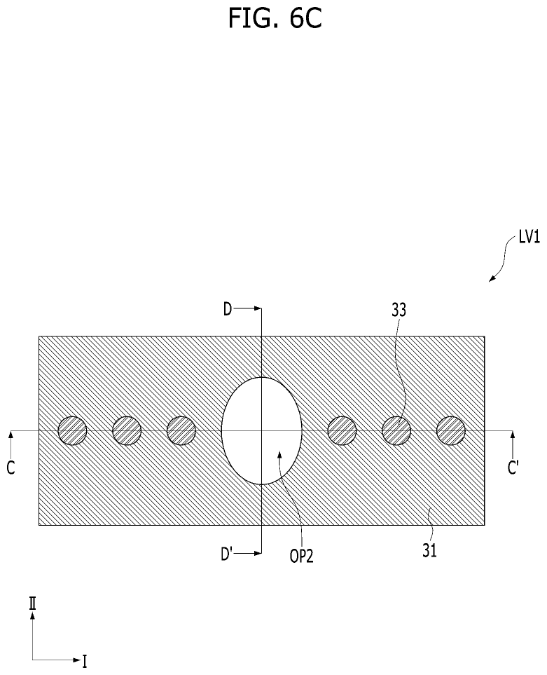

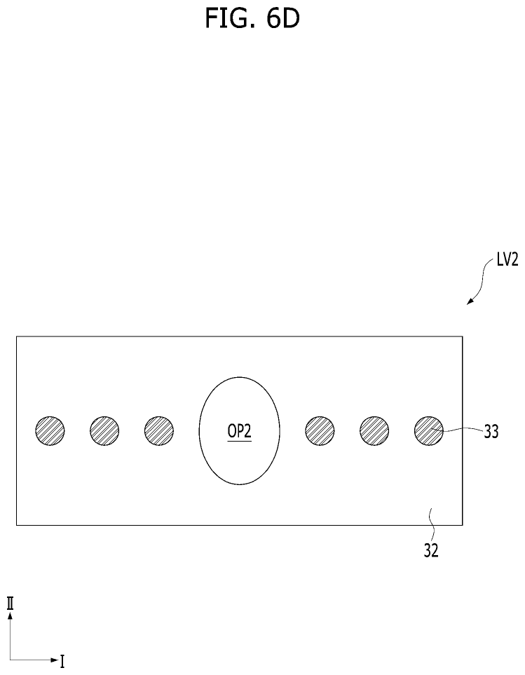

Referring to FIGS. 6A to 6D, the second sacrificial layer 34 may be removed. The second sacrificial layer 34 may be etched using the mask pattern 35 as an etching barrier. The second opening OP2 may be a reopened second opening OP2 produced by selectively etching the second sacrificial layer 34. As an example, the second sacrificial layer 34 may be removed using a strip process.

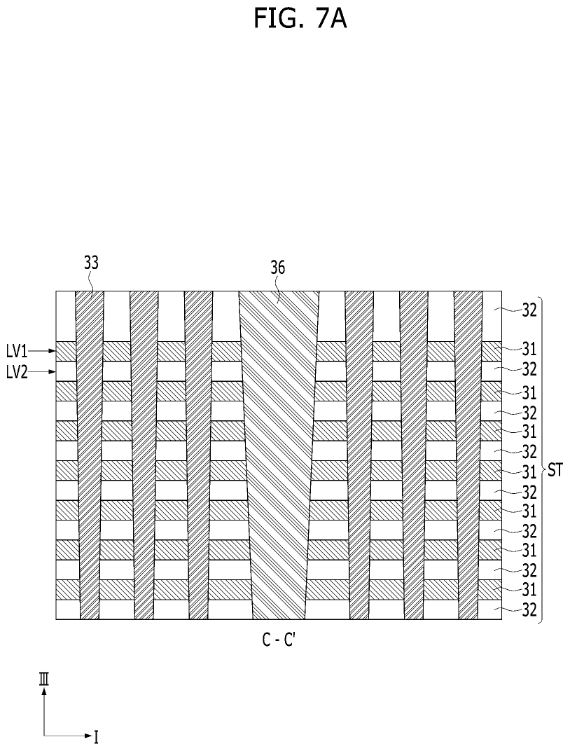

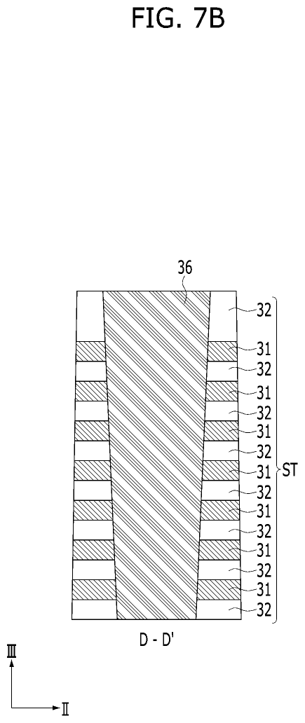

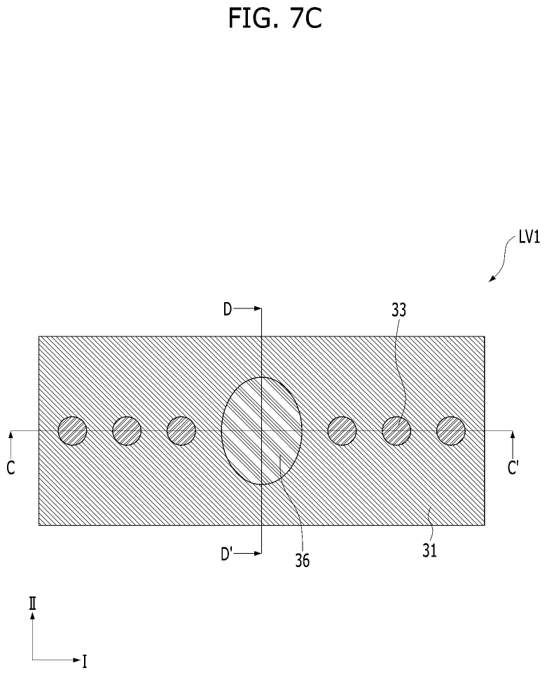

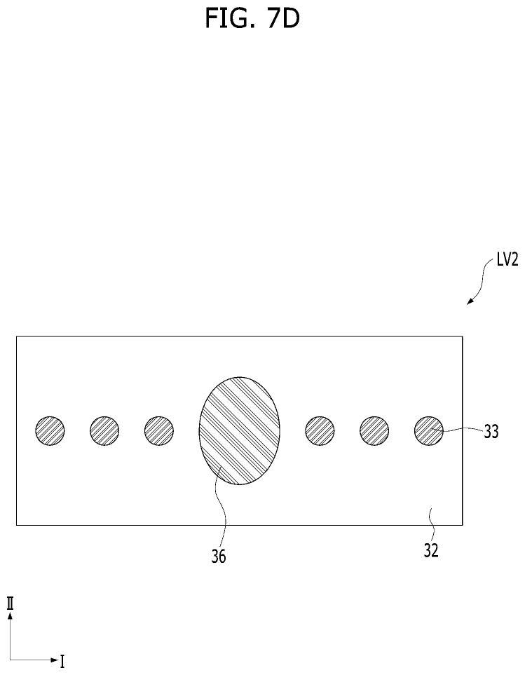

Referring to FIGS. 7A to 7D, a support 36 may be formed in the second opening OP2. As an example, an insulating layer forming support 36 may be formed in the reopened second opening OP2. As an example, the insulating layer may be deposited by a thermal atomic layer deposition (ALD) method, a low pressure chemical vapor deposition (LP-CVD) method, or the like. When the insulating layer is deposited, the insulating layer may also be formed on the stack ST. Subsequently, the insulating layer may be planarized until the stack ST is exposed. When a polishing process is performed, the first sacrificial layers 33 may be used as polishing stop layers. Through this, the support 36 may be formed in the reopened second opening OP2. During the planarization process, the mask pattern 35 may be removed, and the first sacrificial layers 33 may be exposed. Alternatively, before the insulating layer is formed, the mask pattern 35 may be removed. The planarization process may be performed using a chemical mechanical polishing (CMP) process.

In a plan view, the support 36 may have a circular shape, an elliptical shape, a polygonal shape, or the like. As an example, the support 36 as shown in FIG. 7C may have an elliptical shape, and may include a short axis extending in the first direction I and a long axis extending in the second direction II. The support 36 may include an insulating material such as for example an oxide.

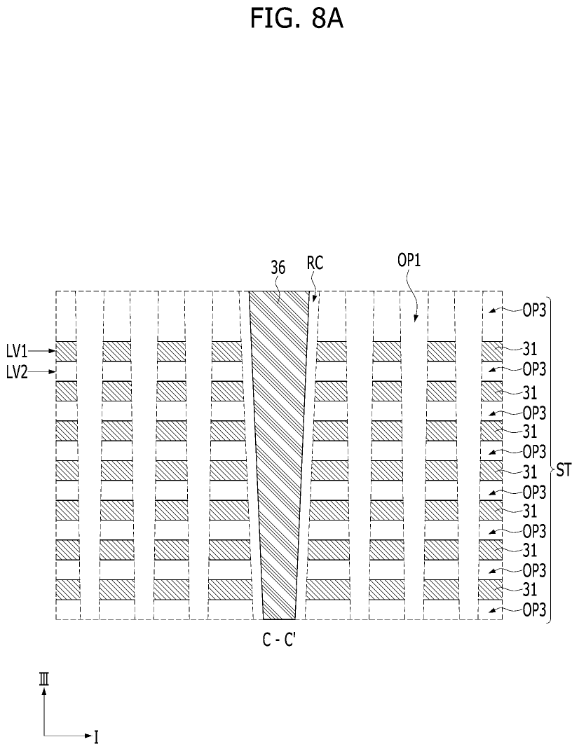

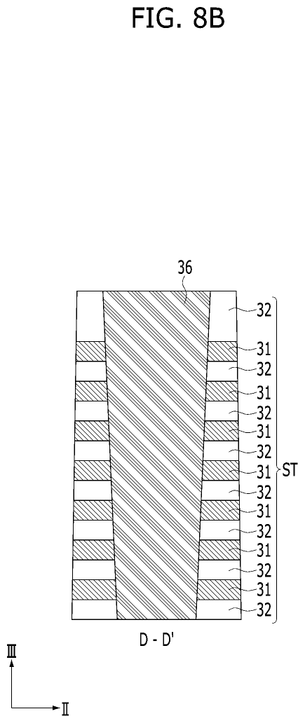

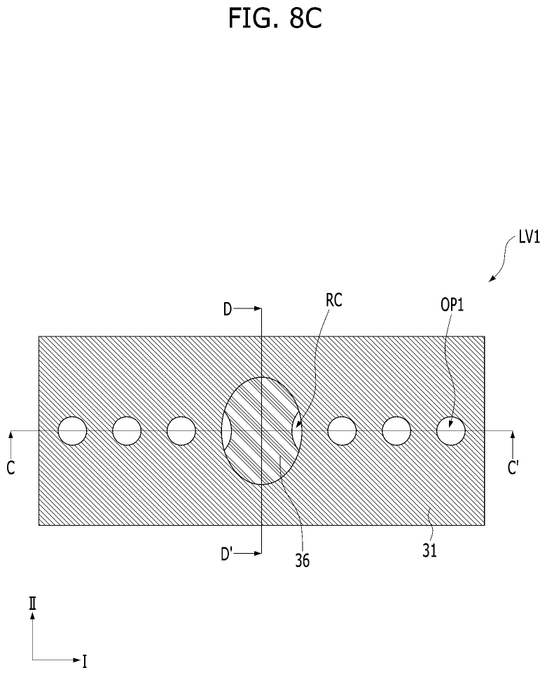

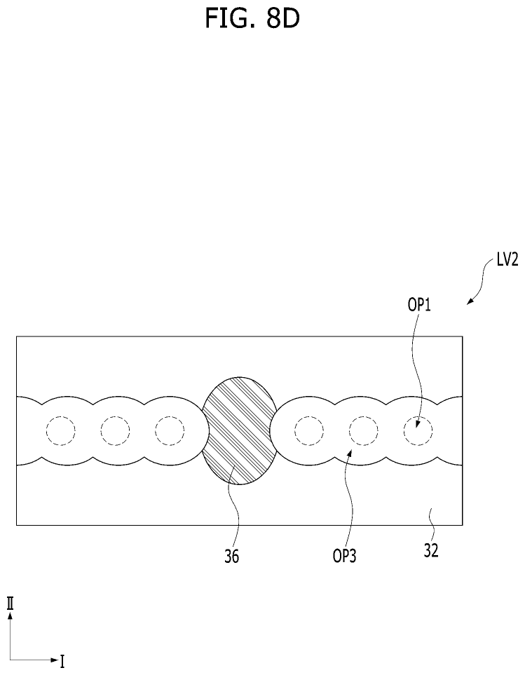

Referring to FIGS. 8A to 8D, the first openings OP1 may be reopened by removing the first sacrificial layers 33. Subsequently, the second material layers 32 may be selectively etched through the first openings OP1. The first openings OP1 may be expanded by etching the second material layers 32, and third openings OP3 interconnecting the first openings OP1 may be formed. The third openings OP3 may be located between the stacked first material layers 31, and may extend in the first direction I. Adjacent first openings OP1 may be connected to each other at the second level LV2 by the third opening OP3. Because the first material layers 31 exist at the first level LV1, the first openings OP1 might not be connected to each other at the first level LV1.

Because the third openings OP3 are formed by expanding the first openings OP1, the shapes of the first openings OP1 may be transferred to the third openings OP3. As an example, when the first opening OP1 includes a circular shape, the third opening OP3 may have a shape in which expanded circular shapes are connected to each other. The third opening OP3 may include irregularities on sidewalls thereof.

Sidewalls of the support 36 may be exposed through the third openings OP3. In the process of etching the second material layers 32, the support 36 may be exposed and the sidewalls of the support 36 may be etched. In such a case, a recess RC may be formed on the sidewalls of the support 36. The recess RC may be formed at the second level LV2, and may extend along the third direction III. As an etching chemical flows into the recess RC, the recess RC may extend between the first material layers 31 and the support 36. The recess RC may extend up to the first level LV1, and a recess RC extending along the third direction III may be formed on the sidewalls of the support 36.

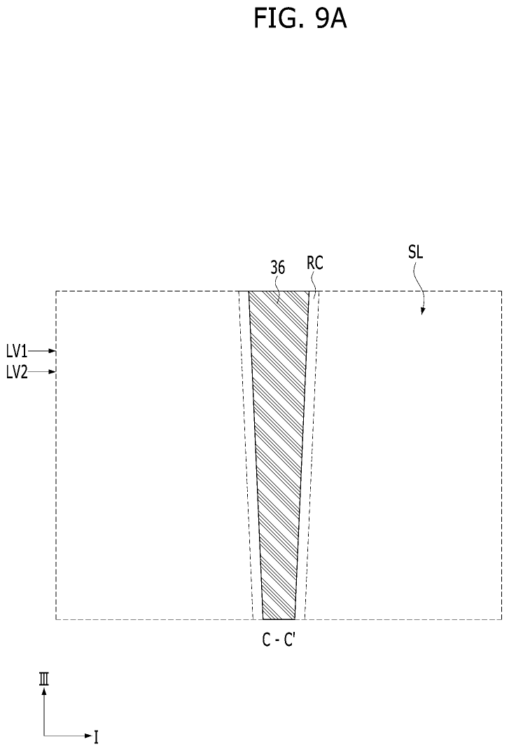

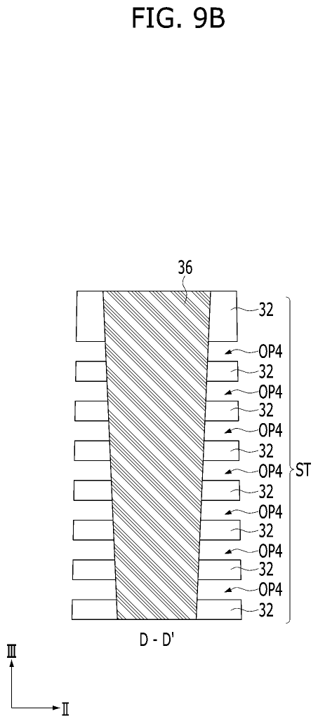

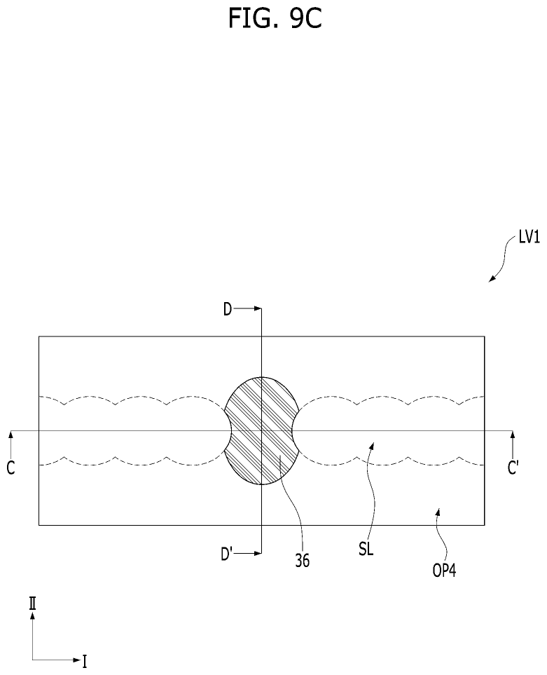

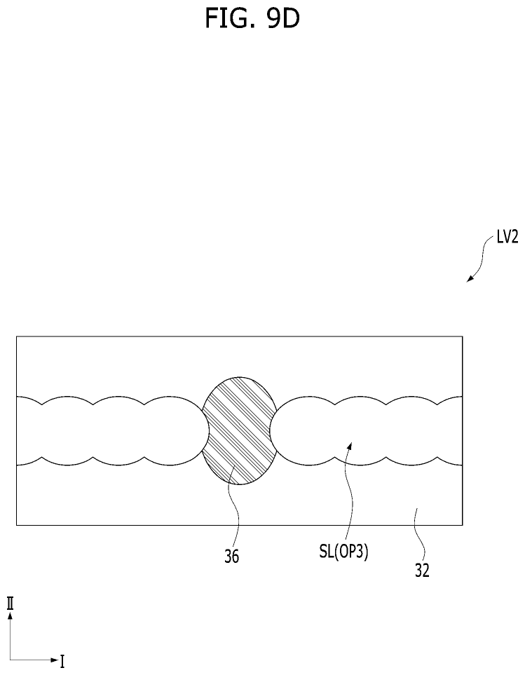

Referring to FIGS. 9A to 9D, the first material layers 31 may be etched through the third openings OP3. An etching chemical may be supplied through the first openings OP1 and the third openings OP3, and the first material layers 31 around the third openings OP3 may be etched by the etching chemical. The first material layers 31 may be removed between the second material layers 32 and between the third openings OP3, and fourth openings OP4 and slits SL may be defined according to regions where the first material layers 31 are removed.

The etching chemical supplied through the first openings OP1 and the third openings OP3 may flow between the stacked second material layers 32. As the first material layers 31 are etched, the third openings OP3 may expand in a horizontal direction to form the fourth openings OP4. The fourth openings OP4 may be located between the second material layers 32. When the fourth openings OP4 are formed, the support 36 may support the second material layers 32 and reduce bending of the stack ST.

The first material layers 31 may be etched between the third openings OP3 by an etching chemical. Through this, the third openings OP3 may expand in the third direction III, and may be interconnected to form the slit SL. The slit SL may be located at a boundary between adjacent memory blocks. The slit SL may extend along the first direction I at the first level LV1 and the second level LV2. The fourth openings OP4 and the slit SL may be connected to each other. The slit SL may include irregularities on sidewalls thereof.

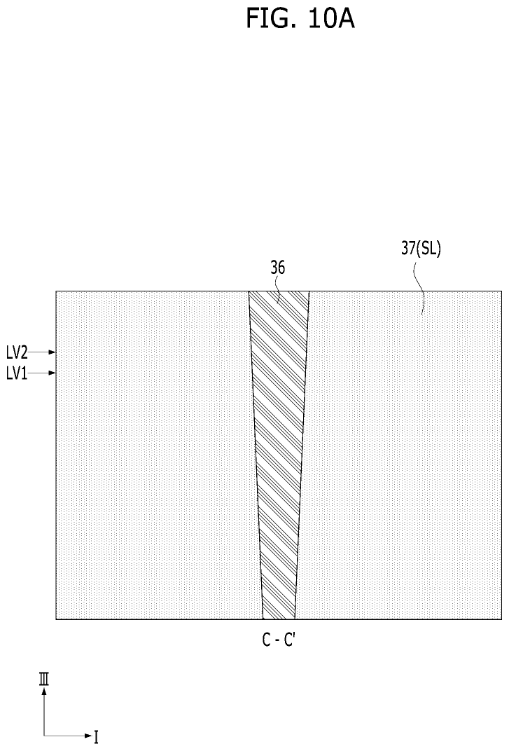

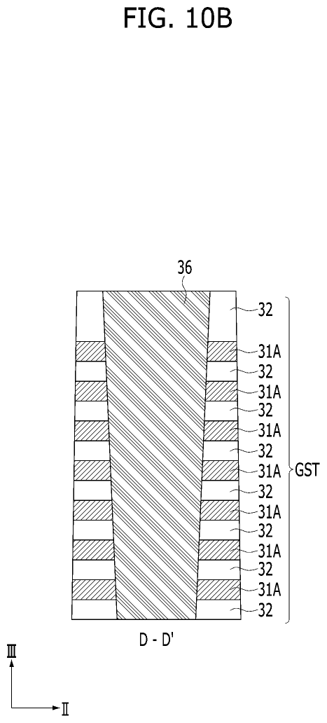

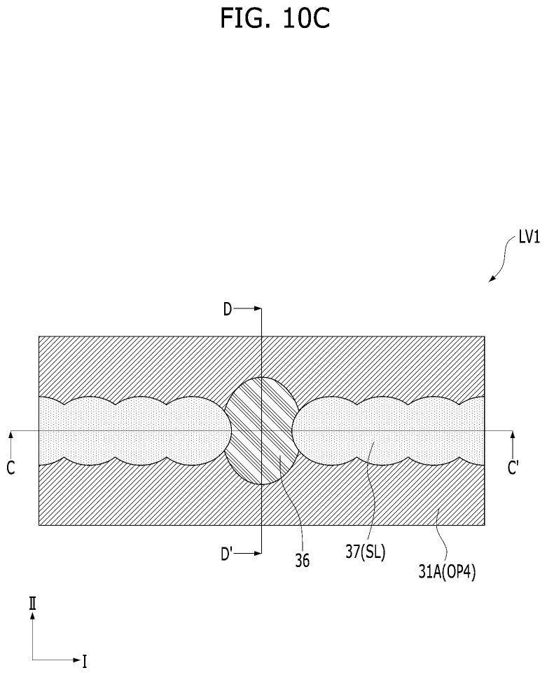

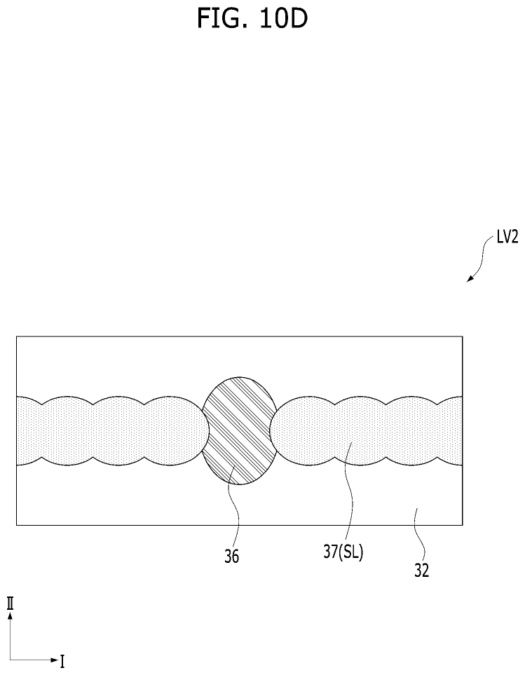

Referring to FIGS. 10A to 10D, third material layers 31A may be formed in the fourth openings OP4. The third material layers 31A may form gate lines, source select lines, drain select lines, and word lines. In one example, a conductive layer may be deposited in the slit SL and the fourth openings OP4. Subsequently, conductive patterns located in the fourth openings OP4 may be separated from each other by etching a portion of the conductive layer formed in the slits SL.

Subsequently, an isolation insulating structure 37 may be formed in the slit SL. The isolation insulating structure 37 may include an insulating material such as for example one or more of an oxide, a nitride, or an air gap. The isolation insulating structure 37 may also include a source contact structure and an insulating spacer surrounding sidewalls of the source contact structure.

According to the manufacturing method described above, the isolation insulating structure 37 may be formed using the first openings OP1, and the support 36 may be formed using the second openings OP2. Instead of forming various types of openings, by forming hole-like openings and then expanding and connecting the openings, a process for forming a three-dimensional semiconductor device may be simplified. By replacing the first material layers 31 with the third material layers 31A through the third openings OP3 after the supports 36 are formed, bending of the stack ST may be reduced.

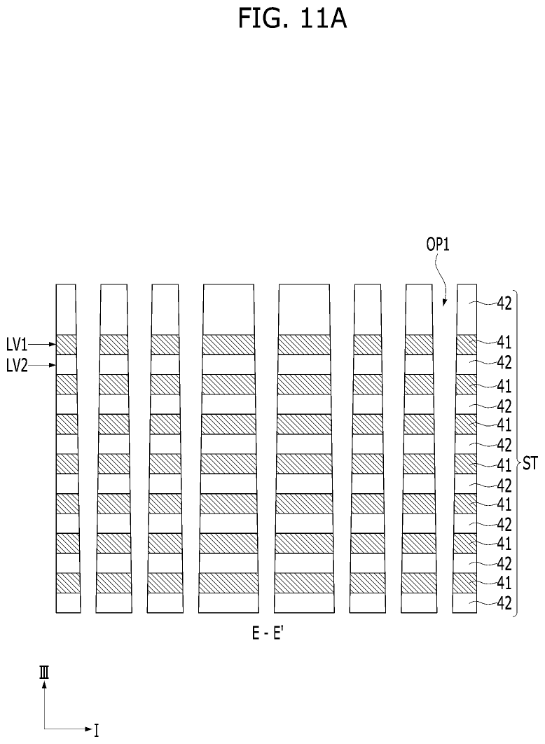

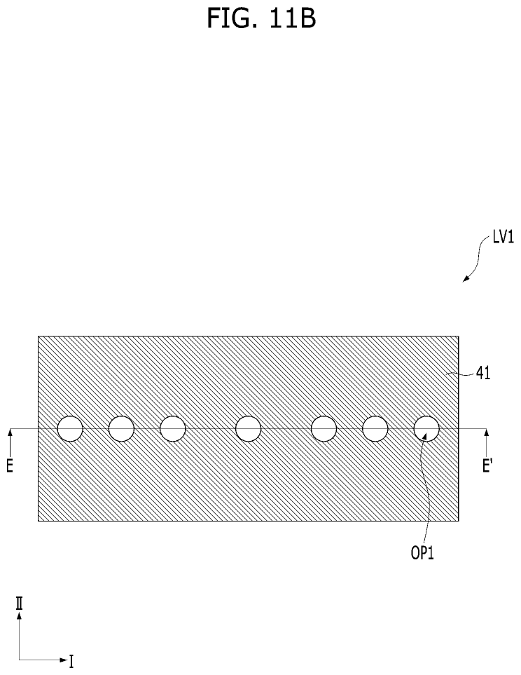

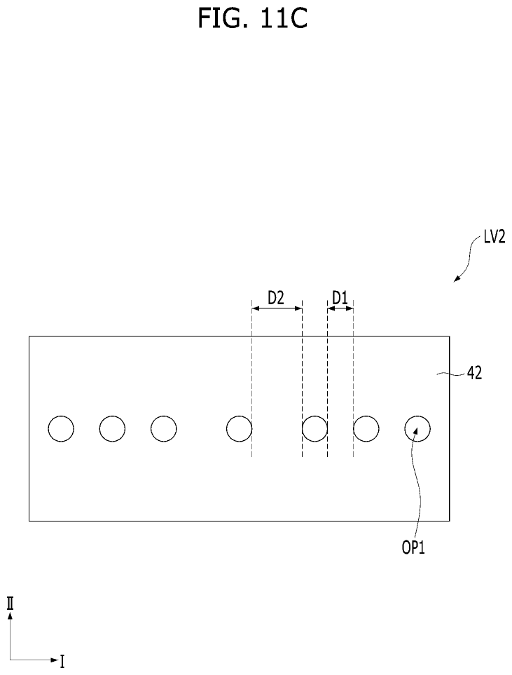

FIGS. 11A, 12A, 13A, 14A, and 15A, FIGS. 11B, 12B, 13B, 14B, and 15B, and FIGS. 11C, 12C, 13C, 14C, and 15C are diagrams for describing manufacturing methods for forming a semiconductor device in accordance with other detailed embodiments. FIGS. 11A, 12A, 13A, 14A, and 15A are cross-sectional views taken along lines E-E′ of FIGS. 11B, 12B, 13B, 14B, and 15B, respectively, FIGS. 11B, 12B, 13B, 14B, and 15B are plan views of a first level LV1 of FIGS. 11A, 12A, 13A, 14A, and 15A, respectively, and FIGS. 11C, 12C, 13C, 14C, and 15C are plan views of a second level LV2 of FIGS. 11A, 12A, 13A, 14A, and 15A, respectively. Hereinafter, the content overlapping with the previously described content will be omitted.

Referring to FIGS. 11A to 11C, a stack ST including first material layers 41 and second material layers 42 that are alternately stacked may be formed. The first material layers 41 may be used to form gate lines such as for example select lines and/or word lines. In one example, the first material layers 41 may each include a sacrificial material such as a nitride or may include a conductive material such as polysilicon and/or metal. The second material layers 42 may each include an insulating material such as for example one or more of an oxide, a nitride, or an air gap.

Subsequently, first openings OP1 may be formed in the stack ST. The first openings OP1 may extend in the third direction III into the stack ST. The first openings OP1 may be arranged along the first direction I. The first openings OP1 may have substantially the same size. As an example, one or more the first openings OP1 may have the same shape and the same width. Through this, the etching environment of the first openings OP1 may be the same or similar, and depth uniformity of the first openings OP1 may be increased. The first openings OP1 may have substantially the same depth. Distances between the first openings OP1 may be substantially the same as or different from each other.

The first openings OP1 may be used to form a support or an isolation insulating structure in a subsequent process, and may be expanded in a subsequent process. Accordingly, the first openings OP1 may be formed to have substantially the same size, but may be arranged in consideration of a size to be expanded in a subsequent process. As shown in FIG, 11C, the first openings OP1 may be arranged to be spaced apart by a first distance D1 or arranged to be spaced apart by a second distance D2 greater than the first distance D1.

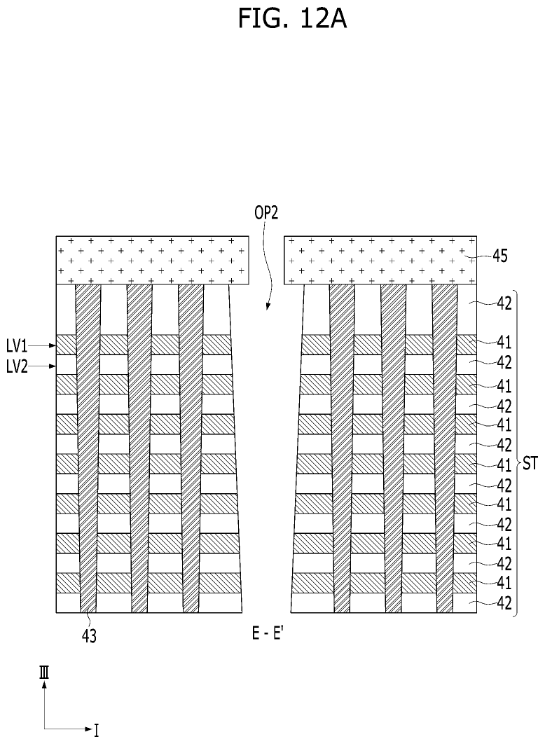

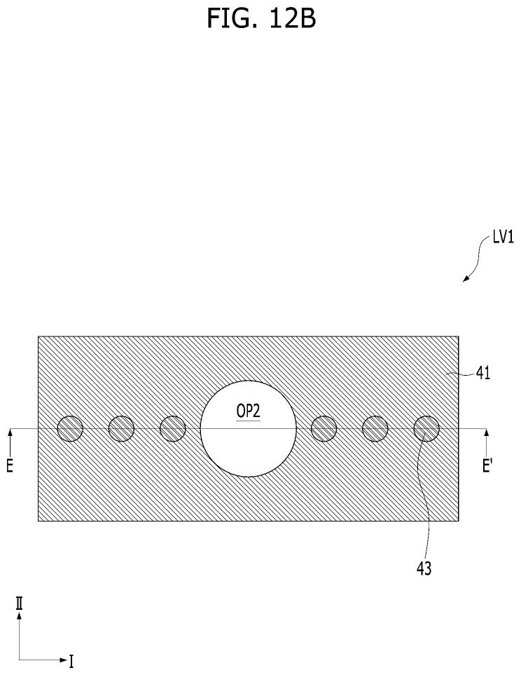

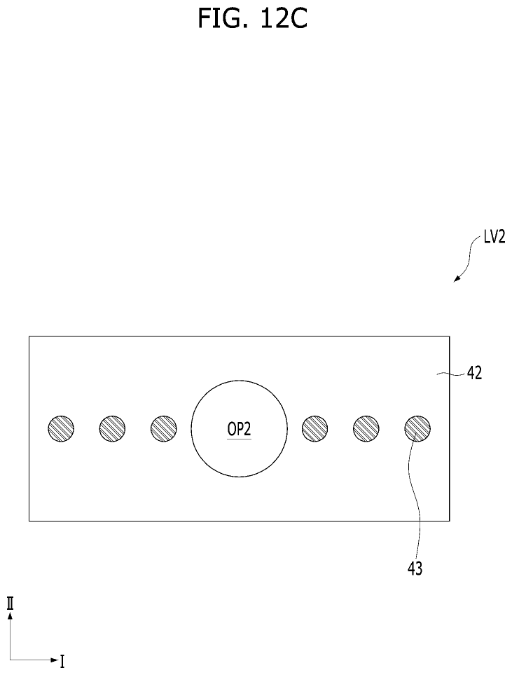

Referring to FIGS. 12A to 12C, a second opening OP2 may be formed in the stack ST. First, sacrificial layers 43 may be formed in the first openings OP1. Subsequently, a mask pattern 45 may be formed on the stack ST to expose at least one first opening OP1 and cover the remaining first openings OP. Subsequently, the sacrificial layer 43 may be selectively etched using the mask pattern 45 as an etching barrier. Through this, the sacrificial layer 43 formed in the at least one first opening OP1 may be selectively removed, and the at least one first opening OP1 may be reopened. Subsequently, the second material layers 42 may be selectively etched through the reopened first opening OP1. In such a case, the second material layers 42 may be etched by a predetermined thickness so that the sacrificial layers 43 formed in the remaining first openings OP1 are not exposed. Subsequently, the first material layers 41 may be selectively etched through the reopened first opening OP1. Through this, at least one of the first openings OP1 may be selectively expanded to form at least one second opening OP2.

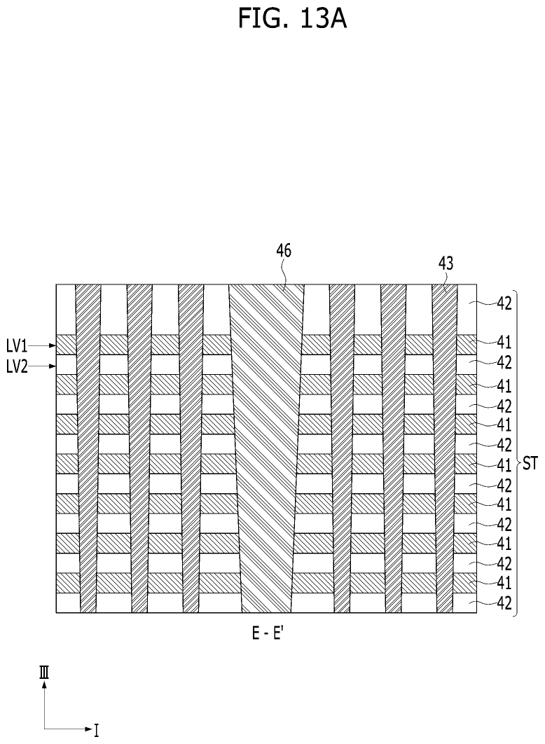

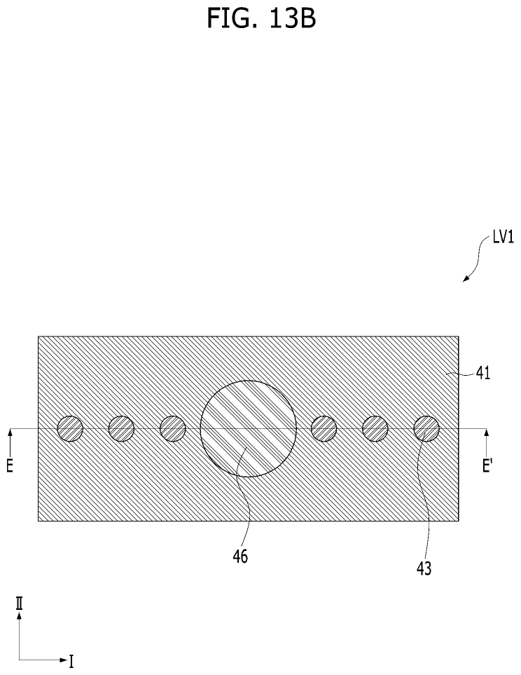

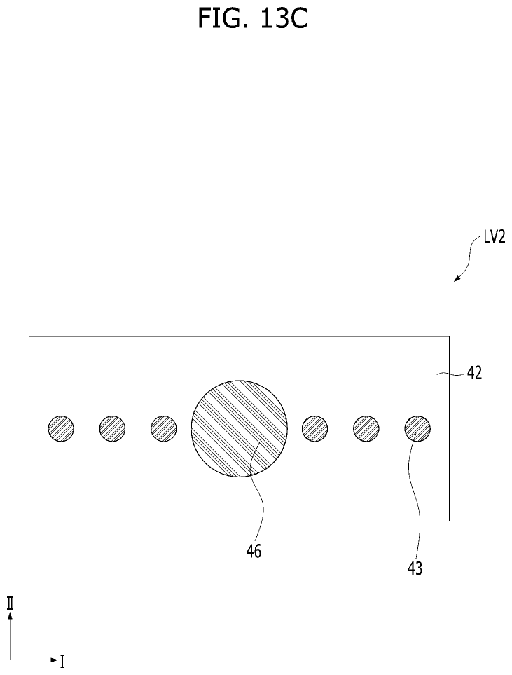

Referring to FIGS. 13A to 13C, a support 46 may be formed in the second opening OP2. As an example, an insulating layer may be formed in the reopened second opening OP2, and the insulating layer may be planarized until the stack ST is exposed. Through this, the support 46 may be formed in the reopened second opening OP2. During the planarization process, the mask pattern 45 may be removed and the sacrificial layers 43 may be exposed. In a plan view, the support 46 may have a circular shape, an elliptical shape, a polygonal shape, or the like.

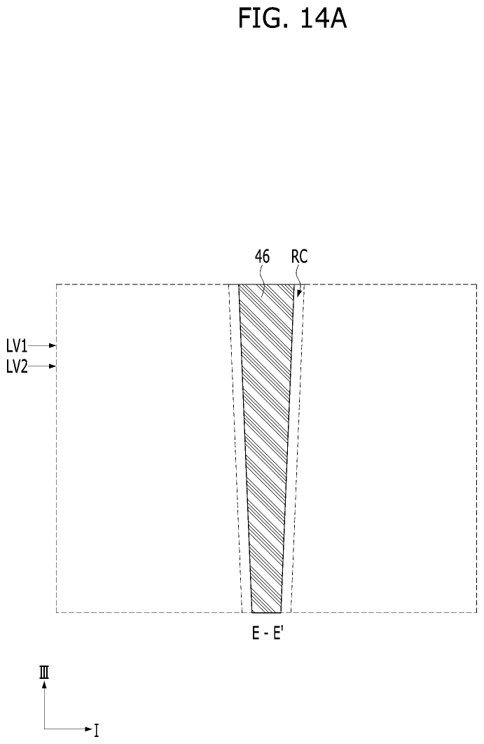

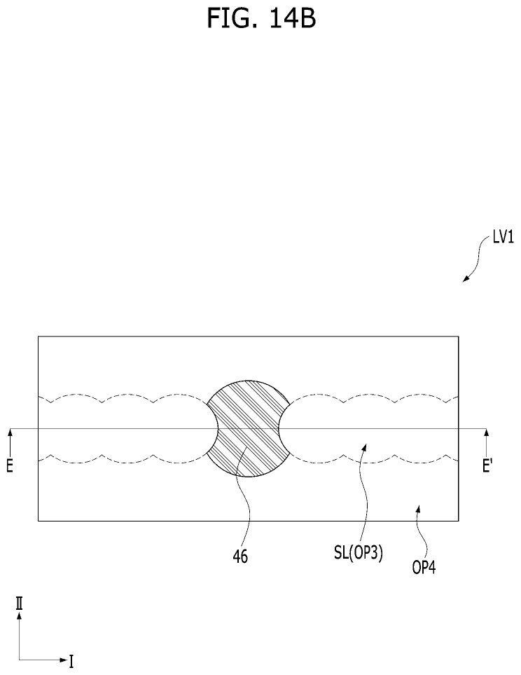

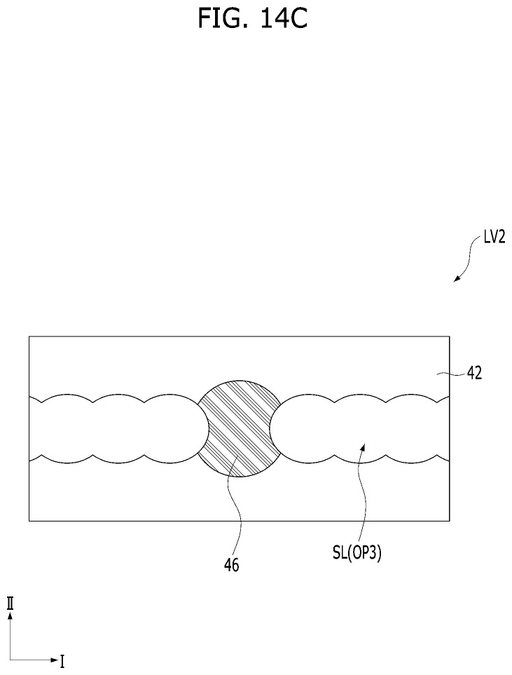

Referring to FIGS. 14A to 14C, the first openings OP1 may be reopened by removing the sacrificial layers 43. Subsequently, the second material layers 42 may be selectively etched through the first openings OP1. Through this, the first openings OP1 may be expanded, and third openings OP3 interconnecting the first openings OP1 may be formed. Sidewalls of the support 46 may be exposed through the third openings OP3 and may be etched. A recess RC may be formed in the sidewalls of the support 46.

Subsequently, the first material layers 41 may be etched through the third openings OP3 to form fourth openings OP4 and a slit SL. When the fourth openings OP4 and the slit SL are formed, the support 46 may support the second material layers 42 and reduce bending of the stack ST.

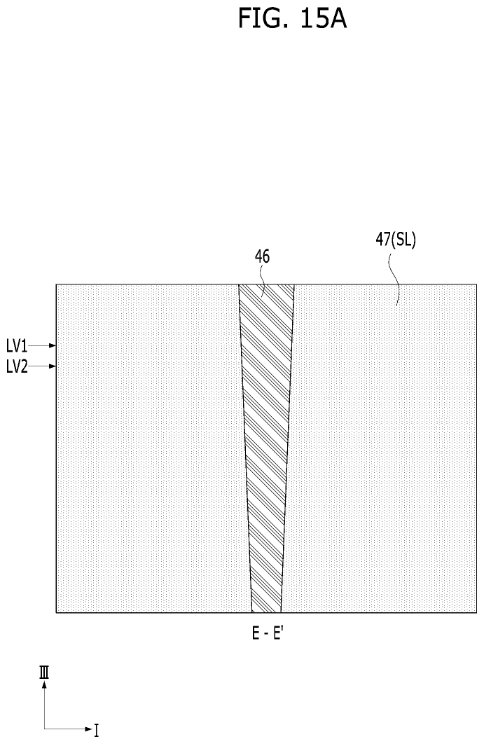

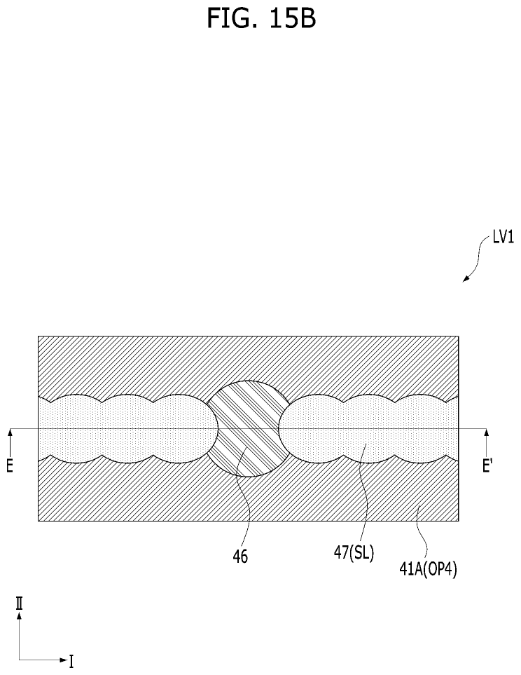

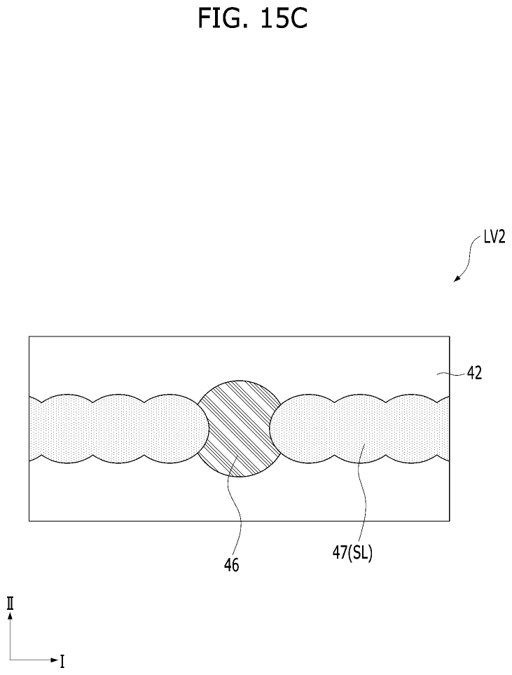

Referring to FIGS. 15A to 15C, third material layers 41A may be formed in the fourth openings OP4. Subsequently, an isolation insulating structure 47 may be formed in the slit SL. The isolation insulating structure 47 may protrude into the support 46.

According to the manufacturing method described above, the support 46 and the isolation insulating structure may be formed using the first openings OP1. By forming the first openings OP1 in the same size and then expanding the first openings OP1, a process for forming a three-dimensional semiconductor device may be simplified. By forming the supports 46 and then etching the first material layers 41 through the third openings OP3, bending of the stack ST may be reduced.

Although embodiments according to the technical details of the present disclosure have been described above with reference to the accompanying drawings, this is only for explaining the embodiments according to various embodiments of the present disclosure, and the present disclosure is not limited to the above embodiments. Various types of substitutions, modifications, and changes for the embodiments may be made by those skilled in the art, to which the present disclosure pertains, without departing from the technical details described in the present disclosure, and it should be construed that these substitutions, modifications, and changes belong to the scope of the present disclosure.

What is claimed is:

1. A semiconductor device comprising:
a first gate structure;
a second gate structure;
an isolation insulation structure configured to extend in a first direction between the first gate structure and the second gate structure, and to have a first width in a second direction intersecting the first direction; and
a first support located between the first gate structure and the second gate structure, and configured to have a second width greater than the first width in the second direction,
wherein the isolation insulation structure protrudes into the first support.

2. The semiconductor device of claim 1, wherein a sidewall of the first support includes a recess, and the isolation insulation structure extends into the recess.

3. The semiconductor device of claim 1, wherein, in a plan view, the first support has a circular shape, an elliptical shape, or a polygonal shape.

4. The semiconductor device of claim 1, wherein, in a plan view, the first support has an elliptical shape, and includes a short axis extending along the first direction and a long axis extending along the second direction.

5. The semiconductor device of claim 4, wherein a sidewall of the first support includes a recess located on the short axis.

6. The semiconductor device of claim 1, wherein the first support is located between a pair of isolation insulation structures, at least one of the pair of isolation insulation structures comprising the isolation insulation structure, and the pair of isolation insulation structures protrude into the first support.

7. The semiconductor device of claim 6, wherein a sidewall of the first support includes a pair of recesses, and the pair of isolation insulation structures extend into the recesses, respectively.

8. The semiconductor device of claim 7, wherein the first support has an elliptical shape, and the pair of recesses face each other along a short axis of the first support having the elliptical shape.

9. The semiconductor device of claim 1, wherein the isolation insulation structure includes irregularities on a sidewall thereof.

10. The semiconductor device of claim 1, wherein the isolation insulation structure includes a convex portion and a concave portion on a sidewall thereof.

11. The semiconductor device of claim 1, wherein the first support includes an oxide.

12. The semiconductor device of claim 1, wherein the first support is located between a contact region of the first gate structure and a contact region of the second gate structure.

13. The semiconductor device of claim 1, further comprising:
a channel structure configured to extend through a cell region of the first gate structure; and
a second support configured to extend through a contact region of the first gate structure and including a dummy channel layer.

14. A manufacturing method of a semiconductor device, the manufacturing method comprising:
forming a stack including first material layers and second material layers that are alternately stacked;
forming first openings in the stack;
forming a second opening located between the first openings, and the second opening having a greater size than the first openings;
forming a support in the second opening;
forming third openings that connect the first openings to each other between the first material layers and that expose the support by etching the second material layers through the first openings; and
replacing the first material layers with third material layers through the third openings.

15. The manufacturing method of claim 14, wherein the first openings and the second opening are arranged in a first direction, and
the first openings each have a first width and the second opening has a second width greater than the first width in a second direction intersecting the first direction.

16. The manufacturing method of claim 14, wherein the second opening is formed when the first openings are formed.

17. The manufacturing method of claim 14, wherein, in the forming of the second opening, at least one of the first openings is selectively expanded to form at least one second opening.

18. The manufacturing method of claim 17, wherein the forming of the second opening comprises:
selectively etching the second material layers through the at least one first opening; and
selectively etching the first material layers through the at least one first opening.

19. The manufacturing method of claim 14, wherein the forming of the support comprises:
forming first sacrificial layers in the first openings;
forming a second sacrificial layer in the second opening;
forming a mask pattern that covers the first sacrificial layers and exposes the second sacrificial layer; and
etching the second sacrificial layer by using the mask pattern as an etching barrier so that the second opening is reopened.

20. The manufacturing method of claim 19, wherein, in the forming of the support, the support is formed in the reopened second opening by using the first sacrificial layers as polishing stop layers.

21. The manufacturing method of claim 20, wherein the forming of the third openings comprises:
removing the first sacrificial layers so that the first openings are reopened; and
selectively etching the second material layers through the reopened first openings.

22. The manufacturing method of claim 19, wherein the first sacrificial layers and the second sacrificial layer each include a material having a high etching selectivity with respect to the first material layers and the second material layers.

23. The manufacturing method of claim 19, wherein the first sacrificial layers and the second sacrificial layer each include at least one or more of amorphous carbon, tungsten, polysilicon, titanium nitride, and tungsten.

24. The manufacturing method of claim 14, wherein, in the forming of the third openings, the second material layers are selectively etched through the first openings to form third openings extending along a first direction.

25. The manufacturing method of claim 14, wherein each of the third openings includes irregularities on a sidewall thereof.

26. The manufacturing method of claim 14, further comprising:
forming a recess on a sidewall of the support exposed through the third openings.

27. The manufacturing method of claim 14, wherein the replacing of the first material layers with third material layers comprises:
forming fourth openings between the second material layers by etching the first material layers through the third openings; and
forming the third material layers in the fourth openings.

28. The manufacturing method of claim 27, wherein, when the fourth openings are formed, the support supports the second material layers.

29. The manufacturing method of claim 14, further comprising:
forming a slit by etching the first material layers through the third openings, wherein the third openings are expanded in a stacking direction to form the slit.

30. The manufacturing method of claim 29, wherein the slit includes irregularities on a sidewall thereof.

31. The manufacturing method of claim 29, further comprising:
forming an isolation insulation structure in the slit.

32. The manufacturing method of claim 31, wherein the isolation insulation structure protrudes into the support.

33. A manufacturing method of a semiconductor device, the manufacturing method comprising:
forming a stack including first material layers and second material layers that are alternately stacked;
forming first openings in the stack;
forming a second opening having a greater size than the first openings by selectively expanding at least one of the first openings;
forming a support in the second opening;
forming third openings that connect the first openings to each other and that expose the support by etching the second material layers through the first openings; and
forming a recess on a sidewall of the support exposed through the third openings.

34. The manufacturing method of claim 33, further comprising:
forming fourth openings between the second material layers by etching the first material layers through the third openings; and
forming third material layers in the fourth openings.

35. The manufacturing method of claim 33, further comprising:
forming a slit by etching the first material layers through the third openings, the slit connecting the third openings to each other; and
forming an isolation insulation structure in the slit.

36. The manufacturing method of claim 35, wherein the isolation insulation structure extends into the recess.

37. The manufacturing method of claim 33, wherein the recess extends between the first material layers and the support.
